(19) United States
(12) Patent Application Publication
(10) Pub. No.: US 2011/0156726 A1
(43) Pub. Date: Jun. 30, 2011

(54) MEASURING SENSOR, FUEL FEED LINE AND METHOD FOR MANUFACTURING A MEASURING SENSOR

(76) Inventors: Gustav Klett, Moessingen (DE); Markus Niemann, Beckingen (DE)

(21) Appl. No.: 12/990,671

(22) PCT Filed: Dec. 1, 2008
(86) PCT No.: PCT/EP08/66522

§ 371 Date: Feb. 14, 2011

(30) Foreign Application Priority Data
May 5, 2008 (DE) 10 2008 001 545.8

(51) Int. Cl. G01R 27/26; B29C 47/00; B29C 45/00

(52) U.S. Cl. 324/663; 264/104

(57) ABSTRACT

A measuring sensor has a hollow body through which a fluid is able to flow. Two sections of a wall of the hollow body form electrodes for a capacitive and/or a resistive measurement and the electrodes are made of a conductive plastic. The measuring sensor may be used in a fuel feed line. A method for manufacturing is also described.

### FIELD OF THE INVENTION

The present invention relates to a measuring sensor, a fuel feed line, and a method for manufacturing a measuring sensor.

### BACKGROUND INFORMATION

Petroleum-based fuel for internal combustion engines may be replaced or supplemented by ethanol. For optimal combustion and energy yield, the combustion process must be adjusted to the ethanol content. Lambda sensors may be used to ascertain the content of ethanol in the fuel during combustion.

### SUMMARY

The present invention relates to a sensor which is directly able to determine the content of ethanol or other fuel additives in petroleum-based fuel.

The present invention relates to a measuring sensor having a hollow body, through which a fluid may flow, two sections of a wall of the hollow body constituting electrodes for a capacitive and/or resistive measurement, the electrodes being made of a conductive plastic.

The measuring sensor may be a capacitive measuring sensor or a measuring sensor for determining a specific electrical conductance value.

The measuring sensor may be integrated in the fuel supply and determine its mixture ratio based on different dielectric constants of conventional and novel fuels.

Another aspect of the present invention is a fuel feed line having a capacitive measuring sensor, the fuel feed line having two wall sections made of conductive plastic which are electrically insulated from one another, the wall sections being designed as electrodes.

In accordance with the present invention, an example method for manufacturing a capacitive measuring sensor is provided having the following steps: injection molding of a hollow base body made of an insulating plastic, the hollow base body having an inlet, an outlet, and two diametrically opposed openings; injection molding of two electrodes made of a conductive plastic; and closure of the openings using the two electrodes.

### BRIEF DESCRIPTION OF THE DRAWINGS

The present invention is explained in greater detail below with reference to preferred exemplary embodiments and the figures.

FIG. 1 shows a perspective view of an example sensor.

FIG. 2 shows an exploded view of the sensor of FIG. 1.

FIG. 3 shows another specific embodiment of a sensor.

FIG. 4 shows another specific embodiment of a sensor.

FIG. 5 shows another specific embodiment of a sensor.

FIG. 6 shows a longitudinal section of another specific embodiment of a sensor.

FIG. 7 shows a side view of the sensor of FIG. 1.

### DETAILED DESCRIPTION OF EXAMPLE EMBODIMENTS

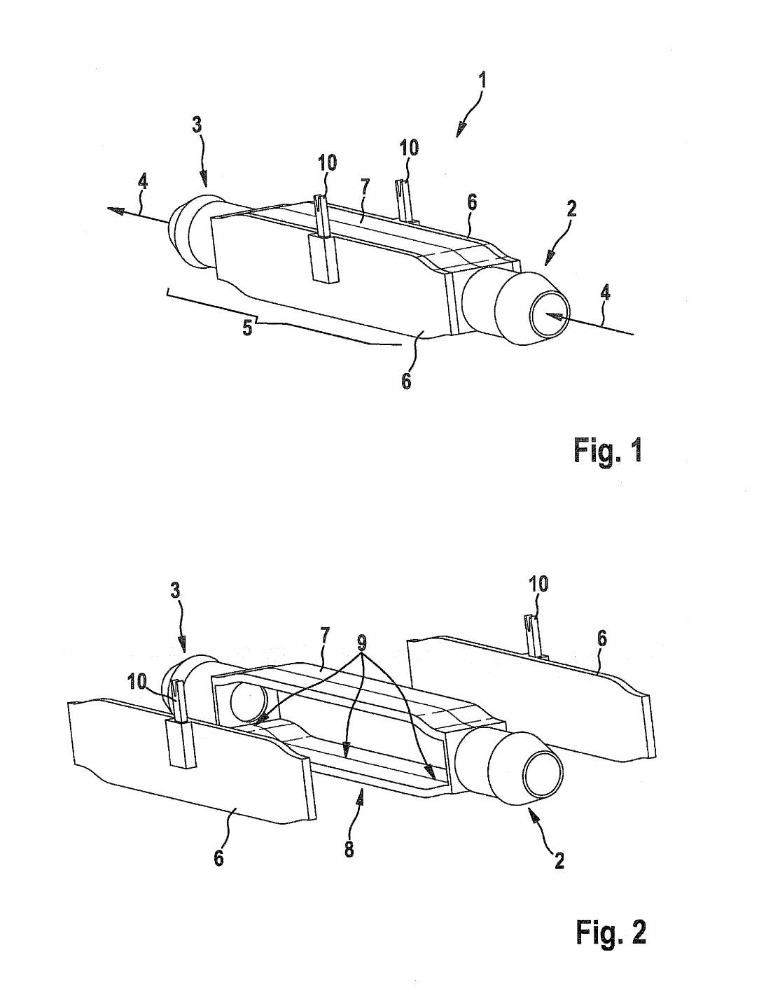

FIG. 1 shows a specific embodiment of a capacitive measuring sensor 1. Capacitive measuring sensor 1 is set up to determine the capacitance of a fluid, i.e., a gas or a liquid while it flows through measuring sensor 1.

Measuring sensor 1 has an inlet 2 via which the fluid is able to flow into measuring sensor 1 and an outlet 3 from which the fluid is able to exit again. The exemplary direction of flow is indicated by arrow 4.

As shown in FIG. 1, capacitive measuring sensor 1 has a closed hollow space 5 whose only openings are inlet 2 and outlet 3. The shape of measuring sensor 1 may also be described as tubular.

The two electrodes 6 which are opposite one another make up a part of the wall of hollow body 5 of measuring sensor 1. The two electrodes 6 are made of a conductive plastic. The conductive plastic may be made, for example, from polyphenylene sulfide (PPS) or polyethylenes (PEs) having metal inlays or metal admixtures. The other walls 7 of measuring sensor 1 are made of an insulating plastic. This insulating plastic may also be manufactured on the basis of a polyphenylene sulfide or polyethylene. Other walls 7 create a space between the two electrodes 6 in such a way that they are not in contact with one another and are consequently electrically insulated from one another. Plastics based on polyamides may be used for this purpose.

FIG. 2 shows an exploded view of the specific embodiment of FIG. 1. Inlet 2, outlet 3, and the other walls 7 make up a base body 8. Base body 8 may be manufactured as a one-piece injection-molded part. As an alternative, base body 8 may be manufactured from two injection-molded half shells that are thermally welded to one another. This is indicated in FIG. 1 by a longitudinal weld 9.

Base body 8 has windows or recesses onto which electrodes 6 may be placed with a positive fit or inserted into them. A tight connection between electrodes 6 and base body 8 may be achieved by welding, cementing, or clamping. According to another embodiment, electrodes 6 are placed on the windows or recesses and subsequently extrusion coated.

Base body 8 is made of plastic. Electrodes 6 are preferably made from the same plastic as base body 8; however, in order to be electrically conductive, they have metallic inclusion bodies, admixtures of metals or graphite.

In the context of this application, a tight connection means that the fluid flowing through, i.e., the fluid or the gas, is only able to flow through inlet 2 and outlet 3.

Contact pins 10 may be attached to electrodes 6. Contact pins 10 may be extrusion coated with the conductive plastic. In one alternative, sockets into which the metallic pins or other contacting means may be snapped into place may be provided on electrodes 6.

The operating principle of the capacitive measuring sensor may be summarized as follows. The two electrodes 6, which are preferably diametrically opposite one another, produce an electrical capacitance together with the hollow space between them. The value of the electrical capacitance is a function of the dielectric constant of the liquid present in the hollow space. The fluids to be detected have a characteristic dielectric constant, so that their mixture ratio changes the capacitance in a known manner. Thus, determining the capacitance conversely makes it possible to infer the composition of the fluid flowing through.

At its inlet 2, measuring sensor 1 has a connecting piece which may be connected to a fuel feed line. In one embodiment, inlet 2 is provided with a hose connecting piece. Outlet 3 may be designed to be identical to inlet 2. Measuring sensor 1 may thus be inserted into the fuel supply or the fuel feed line as an intermediate piece. Measuring sensor 1 may be integrated in a bypass for the measurement or in a principal path of the fuel supply.

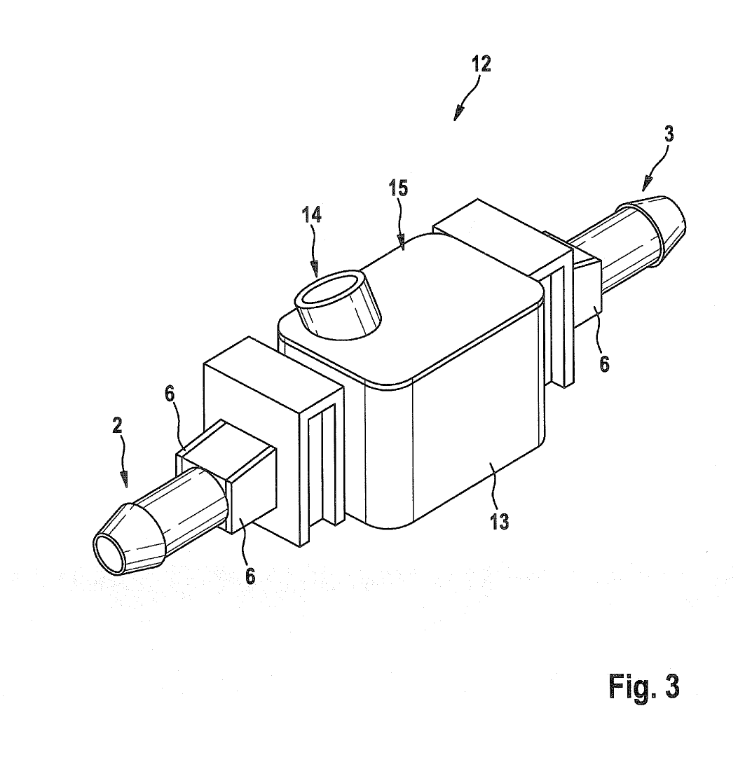

FIG. 3 shows another specific embodiment of a capacitive measuring sensor 12. The capacitive measuring sensor of FIG. 1 is provided with a housing 13 in which the evaluation electronics are already accommodated. Connectors 14 enable the contacting of the measuring sensor and transmit corresponding control signals. A cover 14 seals housing 13 off from environmental influences.

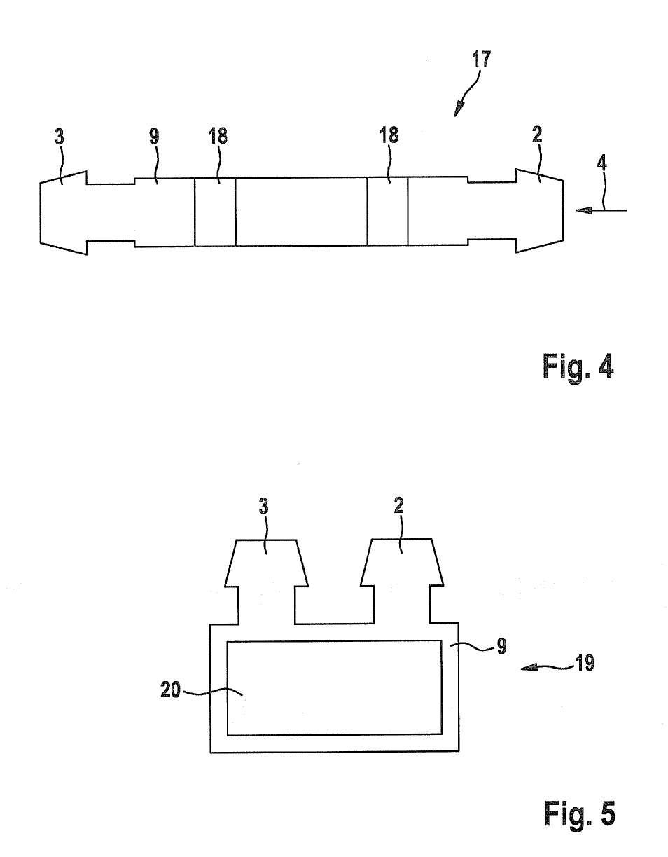

FIG. 4 shows a side view of another specific embodiment of a capacitive measuring sensor 17. As in the previous specific embodiments, capacitive measuring sensor 17 has a base body 9. While electrodes 6 are situated parallel to direction of flow 4 in the previous specific embodiments, electrodes 18 are situated perpendicular to direction of flow 4 in this specific embodiment. However, similar to electrodes 6, electrodes 18 are made from a conductive plastic. Furthermore, electrodes 18 are placed on recesses or are inserted into windows.

FIG. 5 shows another specific embodiment in which the geometric design is different from the previous specific embodiments. Measuring sensor 19 also has a base body 9 made of a plastic. Together with two laterally placed electrodes 20, base body 9 forms a hollow body. The single openings to the hollow body are defined by inlet 2 and outlet 3. However, in contrast to the previous specific embodiments, inlet 2 and outlet 3 are not situated at opposite ends of the hollow body but are instead situated on the same side of the hollow body.

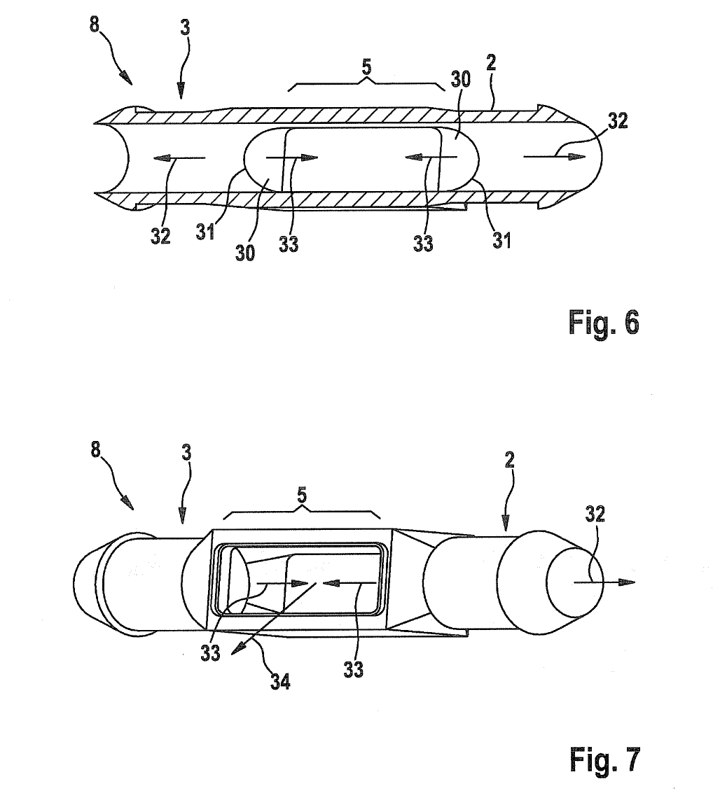

FIGS. 6 and 7 show a longitudinal section and a side view of another specific embodiment of a base body 8 of a measuring sensor. Cross-sections in the area of inlet 2 and of outlet 3 are preferably of equal size. The cross-sections may be of a circular shape for the flange-mounting of hoses. In area 5 of the windows, the cross-section of base body 8 is elevated compared to the windows in at least one direction. The cross-section in a transitional area 30 between the windows and inlet 2 or outlet 3 becomes continuously smaller. This may promote a laminar flow of the fluid through the measuring sensor. Turbulences and gas inclusions that might have an influence on the electrical properties may be avoided.

Base body 8 may be injection-extruded as one piece around a first slide. The first slide is situated in area 5 of the windows. The first slide has sloping lateral surfaces that protrude into the hollow space of base body 8 and define its sloped transitional area 30. Additional rod-shaped slides may be present in the area of inlet 2 and outlet 3. A boundary line 31 is formed in base body 8, the boundary line being produced by the cut body of the first slide and the rod-shaped slides. After the slides are extrusion coated, the rod-shaped slides are removed to the side (arrow 32). The first slide is pushed together (arrow 33) and removed through the window (arrow 34).

Measuring sensor 1 may also be used for determining the specific conductance value of a liquid. The characteristic specific conductance value makes it possible to determine the composition of a liquid.

The specific conductance value and the dielectric constant may be determined concurrently by applying an alternating current signal. The responses obtained: current flow and phase shift of the current flow, making a concurrent determination of the two electrical values possible.

An exemplary list of liquids that may be detected using the measuring sensor includes: gasoline, diesel, ethanol, methanol, rapeseed methyl ester, liquefied petroleum gas (LPG), aqueous urea solution, and mixtures of the aforementioned liquids. Detection of gases is also possible through at least capacitive measurement.

1-13. (canceled)

14. A measuring sensor, comprising:
a hollow body through which a fluid can flow;
wherein two sections of one wall of the hollow body are provided, each having an opening, a respective electrode made from a conductive plastic being placed on or inserted into each opening using a positive connection, the electrodes making at least one of a capacitive and resistive measurement possible.

15. The measuring sensor as recited in claim 14, wherein the wall of the hollow body has at least two additional sections made of an electrically insulating plastic, which create a space between the electrodes.

16. The measuring sensor as recited in claim 14, wherein the hollow body has an inlet for the inflow of the fluid and an outlet for the outflow of the fluid.

17. The measuring sensor as recited in claim 14, wherein the electrodes are situated parallel to a flow direction of the hollow body.

18. The measuring sensor as recited in claim 14, wherein the electrodes are situated perpendicularly to a flow direction of the hollow body.

19. The measuring sensor as recited in claim 14, wherein the electrodes have sockets, into which metallic pins may be snapped into place.

20. The measuring sensor as recited in claim 14, wherein the hollow body has a housing in which evaluation electronics are accommodated.

21. The measuring sensor as recited in claim 14, wherein the electrodes are spaced apart from one another in a direction of the flow direction through the hollow body.

22. The measuring sensor as recited in claim 14, wherein the electrodes and the at least two additional sections of the hollow body are one of welded or cemented to one another.

23. The measuring sensor as recited in claim 21, wherein a cross-section of the inlet and a cross-section of the outlet are expanded in a shape of a funnel to a cross-section in an area of the electrodes.

24. A fuel feed line having a measuring sensor, wherein the fuel feed line has two wall sections made of conductive plastic which are electrically insulated from one another, the wall sections being electrodes.

25. A method for manufacturing a measuring sensor, comprising:
extruding a hollow base body made of an insulating plastic, the hollow base body having an inlet, an outlet and two diametrically opposed openings;
extruding two electrodes made of a conductive plastic; and
closing the openings using the two electrodes.

26. The method for manufacturing as recited in claim 25, wherein the hollow base body is extruded around a slide which defines the two diametrically opposed openings, the slide being pushed together after injection molding and removed through the opening.
